(19) United States
(12) Patent Application Publication
(10) Pub. No.: US 2019/0277800 A1
(43) Pub. Date: Sep. 12, 2019

(54) CONDUCTANCE MEASUREMENT CIRCUIT

(71) Applicant: National Tsing Hua University, Hsinchu City (TW)

(72) Inventors: Yueh-Lin Chung, Hsinchu City (TW); Hsin Chen, Hsinchu City (TW)

(73) Assignee: National Tsing Hua University, Hsinchu City (TW)

(21) Appl. No.: 16/001,922

(22) Filed: Jun. 6, 2018

(30) Foreign Application Priority Data
Mar. 6, 2018 (TW) 107107327

(51) Int. Cl. G01N 27/414; H03F 3/45

(52) U.S. Cl. CPC G01N 27/4148; H03F 3/45179; G01N 27/4145

(57) ABSTRACT

A conductance measurement circuit includes an operation amplifier, a bias current source, a compensation current source, and an output stage circuit. In the operation amplifier, a first input end receives a reference voltage, a second input end is coupled to a tested object, and an output end generates a compensation voltage. The bias current source provides a bias current to a bias end. The compensation current source derives the compensation current from the bias end according to the compensation voltage. The output stage circuit provides a trans-conductance value and an output end equivalent resistance, generates an output current according to the compensation voltage, and generates an output signal according to the output current and the trans-conductance value.

### CROSS-REFERENCE TO RELATED APPLICATION

This application claims the priority benefit of Taiwan application serial no. 10707327, filed on Mar. 6, 2018. The entirety of the above-mentioned patent application is hereby incorporated by reference herein and made a part of this specification.

### BACKGROUND

### Technical Field

The invention relates to a conductance measurement circuit. More particularly, the invention relates to a measurement circuit measuring a change in conductance.

### Description of Related Art

In the field of biological technology, when detecting presence of chemical substances in aqua solution, elements such as ion-sensing-field-effect-transistor (ISFET) elements and nanowires are used most of the time to form a sensing circuit. Wherein, the nanowires acting as the sensing devices may be used to attach the chemical substances. Nevertheless, when the chemical substances are fixed onto the sensing devices, the conductance of the sensing devices changes. The sensing circuit at the back end may be used to detect the change in electrical conductivity of the sensing devices, and the change in the chemical substances in the aqua solution is thereby obtained.

According to the prior art, the sensing devices are operated at a constant-voltage-constant-current (CVCC) environment most of the time by using a voltage feedback mechanism to measure a potential change in the gate caused by the chemical substances through the source of a transistor element. In the prior art, as the conductance of the nanowires is fixed, and the gate voltage of the transistor is reflected to the source voltage, the measurement of the chemical substances is thereby completed. Nevertheless, the influence brought by the chemical substances on the potential of the gate of the transistor element is extremely minor, the signal may not be detected easily. Further, in the prior art, if the output impedance of the current source of the constant current provided is not significantly greater than the impedance of the sensing devices, the current provided may change. The condition of providing the constant voltage and the constant current may not be effectively achieved, which may lead to an error in sensing as a result.

### SUMMARY

The invention provides a conductance measurement circuit configured for detecting a change in conductance of a tested object.

In an embodiment of the invention, a conductance measurement circuit includes an operation amplifier, a bias current source, a compensation current source, and an output stage circuit. In the operation amplifier, a first input end receives a reference voltage, a second input end is coupled to a tested object through a bias end, and an output end generates a compensation voltage. The bias current source is coupled to the bias end and provides a bias current to the bias end. The compensation current source is coupled to the bias end and the operation amplifier and derives a compensation current from the bias end according to the compensation voltage. The output stage circuit is coupled to the operation amplifier, provides a trans-conductance value and an output end equivalent resistance, and generates an output signal according to the compensation voltage.

In an embodiment of the invention, the output stage circuit generates an output current according to the compensation voltage and the trans-conductance value, or generates an output voltage according to the output current and the output end equivalent resistance.

In an embodiment of the invention, the output signal is an output voltage or an output current, wherein a variation in the output voltage or the output current is configured for representing a conductance change in the tested object.

In an embodiment of the invention, the reference voltage multiplied by the conductance change equals the variation of a current value of the output current.

To sum up, the voltages across the tested object is adjusted through the compensation current. When the voltages across the tested object is fixed to be equal to the reference voltage, the output current capable of proving high resolution is generated through the trans-conductance provided by the output stage circuit, so as to detect the change in conductance of the to-be-detected elements.

It is suggested to a higher level that the compensation current may be generated according to the change in the bias voltage of the to-be-detected elements. The variation in conductance of the to-be-detected elements may be obtained according to the current change of the compensation current.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram illustrating a conductance measurement circuit according an embodiment of the invention.

FIG. 2 is a schematic diagram illustrating a measurement circuit according to another embodiment of the invention.

FIG. 3A and FIG. 3B are schematic diagrams illustrating a plurality of implementations of measurement circuits according to another embodiment of the invention.

FIG. 4 is a schematic diagram illustrating a measurement circuit according to still another embodiment of the invention.

FIG. 5 is a chart illustrating relationship between an output voltage generated by a measurement circuit and a change in conductance of a tested object according to an embodiment of the invention.

### DESCRIPTION OF THE EMBODIMENTS

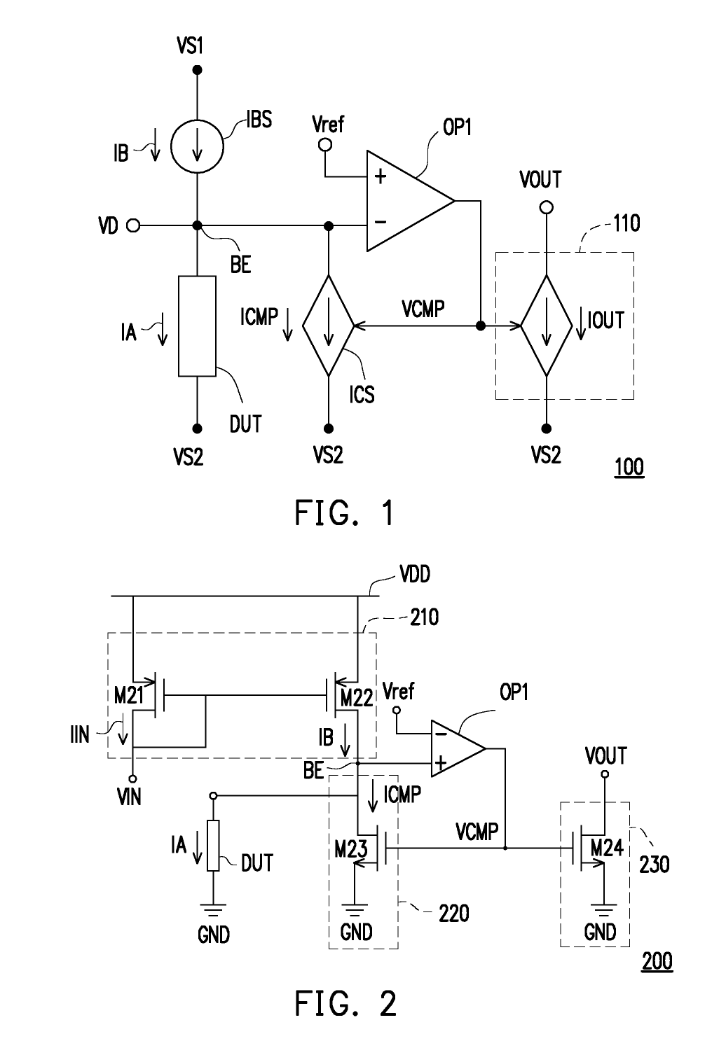

With reference to FIG. 1, FIG. 1 is a schematic diagram illustrating a conductance measurement circuit according an embodiment of the invention. A measurement circuit 100 includes an operation amplifier OP1, a bias current source IBS, a compensation current source ICS, and an output stage circuit 110. A first input end of the operation amplifier OP1 receives a reference voltage Vref, a second input end of the operation amplifier OP1 is coupled to a tested object DUT through a bias end BE, and an output end of the operation amplifier OP1 generates a compensation voltage VCMP. The bias current source IBS receives a first reference power source VS1, is coupled to the bias end BE, and provides a bias current IB to the bias end BE. The compensation current source ICS is coupled to the bias end BE and the operation amplifier OP1. The compensation current source ICS receives the compensation voltage VCMP generated by the output end of the operation amplifier OP1 and derives a compensation current ICMP from the bias end BE according to the compensation voltage VCMP. Wherein, the compensation current source ICS may be serially connected between the bias end BE and a second reference power source VS2, and the compensation current ICMP generated by the compensation current source ICS may flow to the second reference power source VS2 from the bias end BE.

The output stage circuit 110 is coupled to the operation amplifier OP1 for receiving the compensation voltage VCMP. The output stage circuit 110 generates an output current IOUT according to the compensation voltage VCMP. Further, the output stage circuit 110 provides a trans-conductance value and generates the output current IOUT according to the trans-conductance value. Wherein, the output stage circuit 110 is coupled to the second reference power source VS2 and is configured for generating the output current IOUT flowing to the second reference power source VS2.

In terms of overall operation, when a conductance of the tested object DUT changes and the voltages (the reference voltage Vref and a voltage VD at the bias end BE) at the two input ends of the operation amplifier OP1 share a same voltage value, a current IA flowing through the tested object DUT changes. In this way, as the bias current IB is unchanged, the compensation current ICMP generated according to the compensation voltage VCMP thereby changes corresponding to a change in the current IA.

In another aspect, the output stage circuit 110 generates the output current IOUT according to the compensation voltage VCMP. The output stage circuit 110 may generate the output current IOUT having a current value identical to that of the compensation current according to the compensation voltage VCMP. Further, the output stage circuit 110 may provide a trans-conductance value, so as to convert the compensation voltage VCMP into the output current IOUT through the trans-conductance value. Moreover, when the trans-conductance value increases, a signal change of the compensation current may be linearly amplified to change the output current IOUT. The output stage circuit 110 may further linearly convert the output current IOUT to generate the output voltage VOUT according to an output end equivalent resistance provided by the output end. When the compensation current ICMP changes as the conductance of the tested object DUT changes, the output current IOUT may change responding to a change in the conductance of the tested object DUT. Further, the change in the conductance of the tested object DUT may be reflected more evidently through the conversion between the compensation voltage VCMP generated by the trans-conductance value and the output current IOUT as well as the output voltage VOUT accordingly generated.

In the embodiments of the invention, the output stage circuit 110 may also provide the output current IOUT to act as an input signal, which is not particularly limited.

It is assumed that the conductance of the tested object DUT is G_{device}, and a mathematical equation (1) may be provided as follows:

G_{device}×Vref=IB−ICMP (1)

Since the output current IOUT and the compensation current ICMP are respectively generated by the output stage circuit 110 and the compensation current source ICS according to the compensation voltage VCMP, the compensation current ICMP may be equal to the output current IOUT under the same condition that the output stage circuit 110 and the compensation current source ICS respectively generate the output current IOUT and the compensation current ICMP. In this way, the mathematical equation (1) may be rewritten as a mathematical equation (2) as follows:

G_{device}×Vref=IB−IOUT (2)

According to the mathematical equation (2), a mathematical equation (3) may be obtained as follows:

ΔG_{device}×Vref=ΔIOUT=−ΔVOUT/Rₒᵤₜ (3)

Wherein, ΔG_{device} represents the change in the conductance of the tested object DUT, A IOUT represents a variation of the output current IOUT, ΔVOUT represents a variation of the output voltage VOUT, and Rₒᵤₜ represents the output end equivalent resistance provided by the output end of the output stage circuit 110.

It can thus be seen that in the mathematical equation (3), the variation of the output voltage VOUT may be configured to represent the change in conductance ΔG_{device} of the tested object DUT.

Note that in this embodiment, the first reference power source VS1 may be an operating voltage, and the second reference power source VS2 may be a grounding voltage. Alternatively, in other embodiments, the first reference power source VS1 may be the grounding voltage, and the second reference power source VS2 may be the operating voltage. In addition, the tested object DUT may be a nanowire and may be disposed in a chemical solution to detect chemical substances in the chemical solution.

With reference to FIG. 2, FIG. 2 is a schematic diagram illustrating a measurement circuit according to another embodiment of the invention. A measurement circuit 200 includes the operation amplifier OP1, a bias current source 210, a compensation current source 220, and an output stage circuit 230. The input end of the operation amplifier OP1 receives the reference voltage Vref, the other input end of the operation amplifier OP1 is coupled to the bias end BE, and the output end of the operation amplifier OP1 generates the bias voltage VCMP. The tested object DUT is coupled between the bias end BE and a grounding voltage GND.

The bias current source 210 includes a current mirror circuit, and the current mirror circuit is constituted by a transistor M21 and a transistor M22. Wherein, a first end of the transistor M21 receives an operating voltage VDD acting as a reference power source, a control end and a second end of the transistor M21 are coupled to each other, and the control end and the second end of the transistor M21 together receive an input voltage VIN. A first end of the transistor M22 receives the operating voltage VDD acting as the first reference power source, a second end of the transistor M22 is coupled to the bias end BE, and a control end of the transistor M22 is coupled to the control end of the transistor M21.

In terms of the operation of the bias current source 210, the transistor M21 receives the input voltage VIN and generates an input current IIN. The transistor M22 generates a bias current IB through mirroring the input current IIN and provides the bias current IB to the bias end BE through the second end of the transistor M22.

The compensation current source 220 is coupled to the bias end BE and generates the compensation current ICMP according to the compensation voltage VCMP. Wherein, the compensation current source 220 derives the compensation current ICMP from the bias end BE.

In this embodiment, the compensation current source 220 includes a transistor M23. A first end of the transistor M23 is connected to the bias end BE, a control end of the transistor M23 receives the compensation voltage VCMP, and a second end of the transistor M23 is coupled to the grounding voltage GND acting as the second reference power source.

The output stage circuit 230 includes a transistor M24, and a control end of the transistor M24 receives the compensation voltage VCMP. The transistor M24 generates the output current IOUT according to the compensation voltage VCMP and generates the output voltage VOUT at a second end of the transistor M24 according to the output current IOUT. The second end of the transistor M24 is coupled to the grounding voltage GND.

In terms of the operation in this embodiment, the bias current IB is equal to a sum of the current IA and the compensation current ICMP at the tested object DUT. Further, the voltage VD at the bias end BE is substantially equal to the reference voltage Vref, and the conductance G_{device} of the tested object DUT may be written as a mathematical equation (4) as follows:

G_{device}=IA/V_{DS}=IA/(VD−GND) (4)

Wherein, the V_{DS} is a voltage difference between two ends of the tested object DUT, and one end of the tested object DUT receives the voltage VD and the other end of the tested object DUT receives the grounding voltage GND in this embodiment. It thus can be seen that V_{DS}=VD−GND.

When the compensation current ICMP and the output current IOUT are equal, according to the mathematical equation (4), a mathematical equation (5) may be calculated as follows:

ΔVout=ΔG_{device}×V_{DS}×R_{load} (5)

Wherein, ΔVout is a variation of the output voltage VOUT, ΔG_{device} is a variation of the conductance G_{device} of the tested object DUT, and R_{load} is the output end equivalent resistance of the output stage circuit 230.

As such, according to the transistor current equation, a current change in the transistor M24 is proportional to a square of a voltage difference between a gate and a source of the transistor M24. Hence, a voltage change in the compensation voltage VCMP may be amplified according to the output current IOUT generated by the compensation voltage VCMP, and a sensing resolution of the measurement circuit 200 is increased.

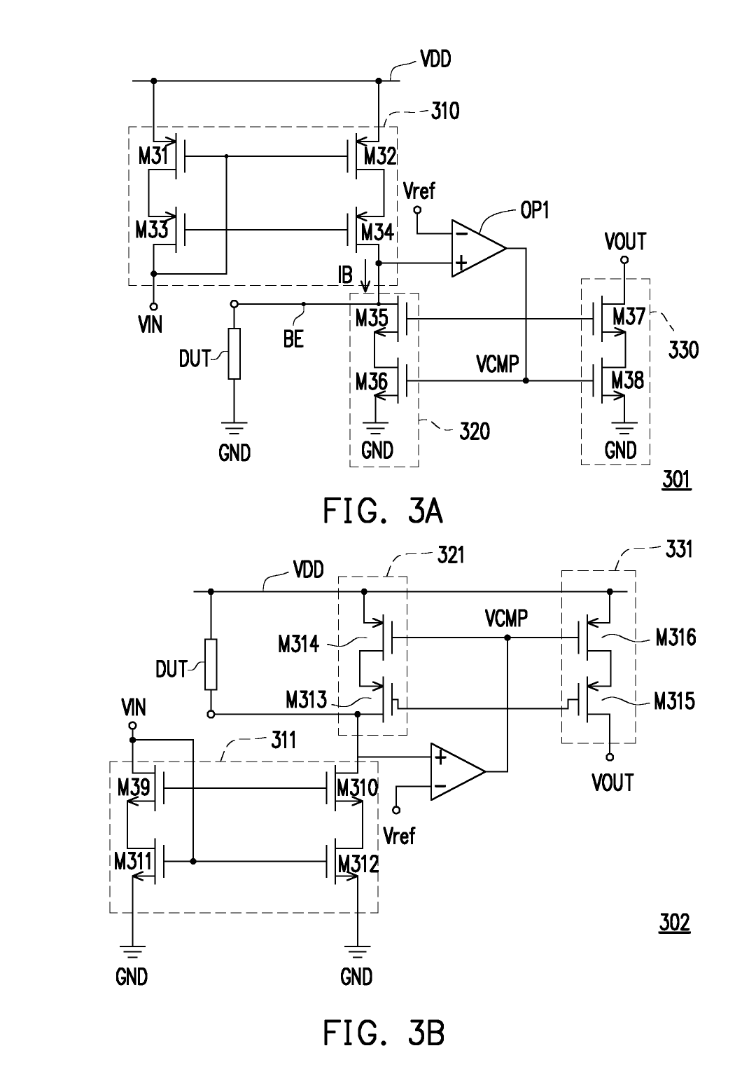

With reference to FIG. 3A and FIG. 3B (FIG. 3B CONTAINS ERRORs to be CORRECTED; SEE TEXT BESIDE THE FIG. 3B), FIG. 3A and FIG. 3B are schematic diagrams illustrating a plurality of implementations of measurement circuits according to another embodiment of the invention. In FIG. 3A, a measurement circuit 301 includes the operation amplifier OP1, a bias current source 310, a compensation current source 320, and an output stage circuit 330. A difference between the measurement circuit 200 in the embodiment of FIG. 2 and the measurement circuit 301 includes that the bias current source 310, the compensation current source 320, and the output stage circuit 330 all includes transistors of a greater number. Wherein, the bias current source 310 includes a current mirror circuit constituted by transistors M31 to M34. A first end of the transistor M31 receives the operating voltage VDD, a second end of the transistor M31 is coupled to a first end of the transistor M33, and a control end of the transistor M31 is coupled to a second end of the transistor M33 to receive the input voltage VIN. A first end of the transistor M32 receives the operating voltage VDD, a control end of the transistor M32 is coupled to the control end of the transistor M31, and a second end of the transistor M32 is connected to a first end of the transistor M34. A control end of the transistor M34 is coupled to a control end of the transistor M33, and a second end of the transistor M34 is coupled to the bias end BE and provides the bias current IB.

The compensation current source 320 includes a transistor M35 and a transistor M36, and the transistor M35 and the transistor M36 are serially connected in sequence between the bias end BE and the grounding voltage GND. Wherein, a control end of the transistor M36 receives the compensation voltage VCMP. The output stage circuit 330 includes a transistor M37 and a transistor M38. The transistor M37 and the transistor M38 are serially connected in sequence. Wherein, a first end of the transistor M37 generates the output voltage VOUT, a control end of the transistor M37 is coupled to a control end of the transistor M35, and a second end of the transistor M37 is coupled to a first end of the transistor M38. A control end of the transistor M38 receives the compensation voltage VCMP, and a second end of the transistor M38 is coupled to the grounding voltage GND.

The operation of the measurement circuit 301 of FIG. 3A is identical to that of the measurement circuit 200 of FIG. 2, and a relevant description thereof is thus omitted. Incidentally, the transistor M31 to the transistor M34 are the P-type transistors, and the transistor M35, the transistor M36, the transistor M37, and the transistor M38 are the N-type transistors in this embodiment.

In another aspect, a measurement circuit 302 illustrated in FIG. 3B is complementary to the measurement circuit 301 of FIG. 3A according to an embodiment. In FIG. 3B, the measurement circuit 302 includes the operation amplifier OP1, a bias current source 311, a compensation current source 321, and an output stage circuit 331. In this embodiment, the bias current source 311 is constituted by N-type transistors M39, M310, M311, and M312, the compensation current source 321 is constituted by P-type transistors M313 and M314, and the output stage circuit 331 is constituted by P-type transistors M315 and M316.

Note that the measurement circuit 301 and the measurement circuit 302 provided by the embodiments of the invention adopt a circuit structure using a circuit mirror to perform current compensation and generate the output voltage. A linear region of the output voltage is not limited by operating regions of the transistors. Regardless of whether the transistors are operated in a saturation region or in a subthreshold region, linearity of the measurement circuits is maintained. Further, in the measurement circuit 301 and the measurement circuit 302 provided by the embodiments of the invention, differences among initial parameters of the circuit elements may be ignored. The variation in the conductance of the tested object may be measured to calculate an amount of the chemical substances.

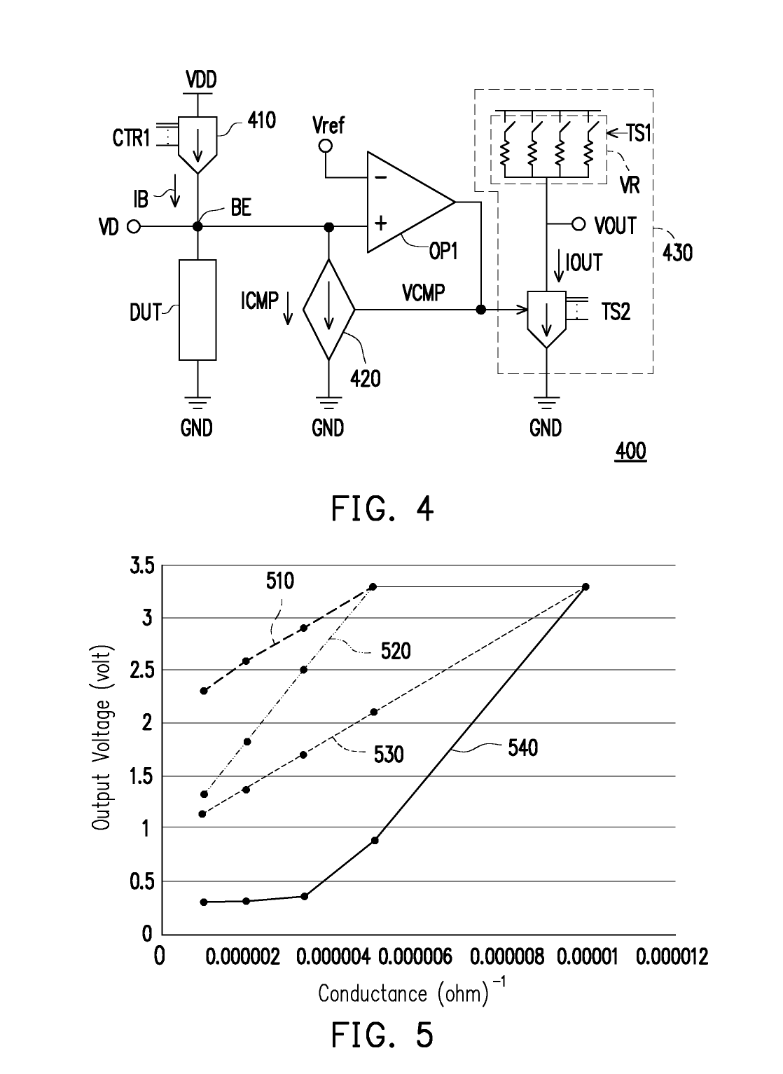

With reference to FIG. 4(FIG. 4 CONTAINS ERRORs to be CORRECTED; SEE TEXT BESIDE THE FIG. 4), FIG. 4 is a schematic diagram illustrating a measurement circuit according to still another embodiment of the invention. A measurement circuit 400 includes the operation amplifier OP1, a bias current source 410, a compensation current source 420, and an output stage circuit 430. In addition, the tested object DUT is coupled between the bias end BE and the grounding voltage GND. The two input ends of the operation amplifier OP1 respectively receive the reference voltage Vref and the voltage VD at the bias end BE and generate the compensation voltage VCMP. The bias current source 410 receives a control signal CTR1 and provides the bias current IB to the bias end BE. Wherein, the bias current source 410 may adjust a current value of the bias current IB according to the control signal CTR1.

The compensation current source 420 is coupled between the bias end BE and the grounding voltage GND, and the compensation current source 420 generates the compensation current ICMP according to the compensation voltage VCMP. The output stage circuit 430 receives the compensation voltage VCMP and generates the output current IOUT according to the compensation voltage VCMP. In this embodiment, the output stage circuit 430 receives a current adjustment signal TS2 and adjusts the output current IOUT according to the current adjustment signal TS2. In addition, the output stage circuit 430 also includes a variable resistance VR. The variable resistance VR receives a resistance adjustment signal TS1 and determines a resistance value of the variable resistance VR according to the resistance adjustment signal TS1. Through adjusting the output current IOUT and the variable resistance VR, sensibility of a measurement mechanism of the measurement circuit 400 is thereby enhanced.

In this embodiment, the variable resistance VR includes a plurality of switches and a plurality of resistances, wherein each of the switches is serially connected to each of the resistances to form a resistance switch train. Each of the switches receives the resistance adjustment signal TS1 to be turned on or cut off. The resistance switch train with the switch being turned on may be configured to receive the output current IOUT and accordingly generates the output voltage VOUT.

The above-mentioned implementation of the variable resistance VR serves as an example only, and the implementations of the variable resistance common-known to people having ordinary skill in the art may be applied to the invention with no particular limitation.

With reference to FIG. 5, FIG. 5 is a chart illustrating relationship between an output voltage generated by a measurement circuit and a change in conductance of a tested object according to an embodiment of the invention. A curve 510 illustrates measuring with a tested object of 100k ohms and enabling an output stage circuit to provide a resistance of 100k ohms to generate an output voltage; a curve 520 illustrates measuring with a tested object of 100k ohms and enabling an output stage circuit to provide a resistance of 200k ohms to generate an output voltage; a curve 530 illustrates measuring with a tested object of 200k ohms and enabling an output stage circuit to provide a resistance of 100k ohms to generate an output voltage; a curve 540 illustrates measuring with a tested object of 200k ohms and enabling an output stage circuit to provide a resistance of 200k ohms to generate an output voltage. It can thus be seen that the variation in conductance of the tested object may be detected by the measurement circuit provided by the embodiments of the invention, and the voltage signal change of the output voltage may be generated through resistance (load resistance) conversion provided by the output stage circuit. In the embodiments of the invention, when an output linear range of the measurement circuit is 1V to 3.3V, the output voltage generated may be amplified effectively. At the same time, a resistance value of the load resistance may be adjusted, so as to change the resolution of the measurement circuit and increase the performance of the measurement circuit.

In view of the foregoing, in the embodiments of the invention, the voltages across two ends of the tested object are maintained to be the constant voltages, and the output voltage is generated through current compensation. In this way, the change in conductance of the tested object may be obtained through changing the output voltage. In addition, in the embodiments of the invention, the trans-conductance value is provided, the compensation voltage is converted into the compensation current, and the change in the compensation current is amplified to generate the output voltage. Therefore, when measuring the conductance, enhanced resolution and sensibility are effectively provided, and performance of the measurement circuit is increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A conductance measurement circuit, comprising:
an operation amplifier, a first input end of the operation amplifier receiving a reference voltage, a second input end of the operation amplifier being coupled to a tested object through a bias end, an output end of the operation amplifier generating a compensation voltage;
a bias current source, coupled to the bias end and providing a bias current to the bias end;
a compensation current source, coupled to the bias end and the operation amplifier and deriving a compensation current from the bias end according to the compensation voltage; and
an output stage circuit, coupled to the operation amplifier, providing a trans-conductance value and an output end equivalent resistance, generating an output signal according to the compensation voltage.

2. The measurement circuit as claimed in claim 1, wherein the output stage circuit generates an output current according to the compensation voltage and the trans-conductance value and generates an output voltage according to the output current and the output end equivalent resistance.

3. The measurement circuit as claimed in claim 1, wherein the output signal is an output voltage or an input current, wherein a variation in the output voltage or the output current is configured for representing a conductance change in the tested object.

4. The measurement circuit as claimed in claim 3, wherein the reference voltage multiplied by the conductance change equals the variation of a current value of the output current.

5. The measurement circuit as claimed in claim 1, wherein the bias current source comprises:
a current mirror circuit, receiving an input voltage, generating an input current according to the input voltage, and mirroring the input current to generate the bias current.

6. The measurement circuit as claimed in claim 5, wherein the current mirror circuit comprises:
a first transistor, a first end of the first transistor being coupled to a first reference power source, a control end and a second end of the first transistor being coupled to each other and receiving the input voltage together; and
a second transistor, a first end of the second transistor being coupled to the first reference power source, a control end of the second transistor being coupled to the control end of the first transistor, a second end of the second transistor generating the bias current.

7. The measurement circuit as claimed in claim 6, wherein the current mirror circuit further comprises:
a third transistor, coupled between a path in which the first transistor receiving the input voltage; and
a fourth transistor, coupled between a coupling path in which the second transistor being coupled to the bias end, a control end of the fourth transistor being coupled to a control end of the third transistor.

8. The measurement circuit as claimed in claim 6, wherein the compensation current source comprises:
a third transistor, a first end of the third transistor being coupled to the bias end, a second end of the third transistor being coupled to a second reference power source, a control end of the third transistor receiving the compensation voltage.

9. The sensing circuit as claimed in claim 8, wherein the output stage circuit comprises:
a fourth transistor, a control end of the fourth transistor receiving the compensation voltage, a first end of the fourth transistor providing the output current, a second end of the fourth transistor receiving the second reference power source, wherein the fourth transistor provides the trans-conductance value.

10. The measurement circuit as claimed in claim 8, wherein the first reference power source is an operating voltage, and the second reference power source is a grounding voltage, or the first reference power source is the grounding voltage, and the second reference power source is the operating voltage.

11. The measurement circuit as claimed in claim 9, wherein the compensation current source further comprises a fifth transistor, serially connected between a coupling path in which the third transistor being coupled to the bias end,
the output stage circuit further comprising a sixth transistor serially connected and coupled to the fourth transistor, a control end of the sixth transistor being coupled to a control end of the fifth transistor.

12. The measurement circuit as claimed in claim 1, wherein the bias current source receives a control signal and adjusts the bias current according to the control signal.

13. The measurement circuit as claimed in claim 1, wherein the output stage circuit receives a current adjustment signal and adjusts the output current according to the current adjustment signal.

14. The measurement circuit as claimed in claim 1, wherein the output stage circuit comprises a variable resistance,
wherein the output stage circuit adjusts a resistance value of the variable resistance according to a resistance adjustment signal and enables the output current to flow through the variable resistance to generate the output voltage.

15. The measurement circuit as claimed in claim 13, wherein the variable resistance comprises:
a plurality of switches, each of the switches being controlled by the resistance adjustment signal to be turned on or cut off;
a plurality of resistances, being serially connected to the switches to form a plurality of resistance switch trains, the resistance switch trains receiving the output current to generate the output voltage.

16. The measurement circuit as claimed in claim 1, wherein the tested object is a nanowire.
